(19) United States
(12) Patent Application Publication
(10) Pub. No.: US 2007/0114580 A1
(43) Pub. Date: May 24, 2007

(54) Nonvolatile semicondutor storage device and manufacturing method thereof

(75) Inventor: Noriaki Kodama, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kanagawa (JP)

(21) Appl. No.: 11/592,297

(22) Filed: Nov. 3, 2006

(30) Foreign Application Priority Data
Nov. 24, 2005 (JP) 2005-338032

(51) Int. Cl. H01L 29/76

(52) U.S. Cl. 257/288

(57) ABSTRACT

A nonvolatile semiconductor storage device includes a plurality of memory cells, each including a drain formed above a substrate, a source formed at a bottom of a groove in the substrate, a floating gate formed above the substrate between the drain and a side surface of the groove, and a control gate formed above the floating gate. The groove is shared by adjacent memory cells. The side surface of the groove is substantially aligned with a side end of the floating gate. The groove is filled with an insulating film.

### BACKGROUND OF THE INVENTION

1. Field of the Invention

The present invention relates to a nonvolatile semiconductor storage device and a method of manufacturing the same and, particularly, to a nonvolatile semiconductor storage device and a method of manufacturing the same which inject electrons to a storage node such as a floating gate or a trap insulating film from the source side.

2. Description of Related Art

A nonvolatile semiconductor storage device which stores information by accumulating electrons in a storage node such as a floating gate has been known. In such a nonvolatile semiconductor storage device, hot electrons are generated at the drain side and then injected to a floating gate to thereby write data. This injection mechanism is called Channel Hot Electron Injection (CHEI). However, the generation of hot electrons at the drain side requires lots of current to flow into a memory cell, and large write current and long write time are problems to be solved in recent high capacity storages.

To address these problems, Source Side Injection (SSI) that injects hot electrons from the source side of a channel area has been proposed. In a nonvolatile semiconductor storage device which employs this mechanism, a high-resistance area is disposed in the vicinity of the source, so that high electric field can be generated on the source side of the channel area with a relatively low voltage. Electrons are accelerated by the high electric field to become hot electrons, which are injected into a floating gate. Such a nonvolatile semiconductor storage device shows high injection efficiency, enabling writing to a memory cell with smaller write current. This reduces overall write current. If the current consumption at the time of writing is equal injecting hot electrons from the source side enables writing to a greater number of memory cells at a time. This is disclosed in Japanese Unexamined Patent Application Publications Nos. 7-94609 (Hisamune et. al.) and 2000-188344 (Kitade), for example.

FIG. 4 depicts the structure of the nonvolatile semiconductor storage device which is taught by Hisamune et. al. As shown in FIG. 4, in a nonvolatile semiconductor storage device 10 of this related art, a drain 2 and a source 3 are formed on the surface of a semiconductor substrate 1. A floating gate 4 is separated from the source 3 with an offset area 6 interposed therebetween. Above the floating gate 4, a second gate insulating film 7 and a control gate 8 are laminated on another.

In the nonvolatile semiconductor storage device 10, the offset area 6 is equivalent to the high-resistance area described above. If a voltage is applied to the drain 2 and the control gate 8, high electric field concentration occurs in the channel close to the source 3 because the offset area 6 is high resistance. The high electric field generates hot electrons, which are then injected to the floating gate 4 for writing to a memory cell. To erase data, electrons are ejected from the floating gate 4 by Fowler-Nordheim (FN) tunnel current.

Japanese Patent No. 2798990 (Yoshikawa) discloses a nonvolatile semiconductor storage device in which a semiconductor substrate has a groove where a source is formed at its bottom. In the nonvolatile semiconductor storage device taught by Yoshikawa, a control gate extends from above a floating gate along the side surface of the groove.

In the nonvolatile semiconductor storage device described in Hisamune et. al. and Kitade, the offset area 6 should be a prescribed size or larger in order to cause the electric field concentration to occur on the source side to generate hot electrons. For example, the offset area 6 should be such that a distance between the source 3 and the position below the floating gate 4 is 100 nm to 200 nm. The offset area 6 is formed horizontally on the surface of the semiconductor substrate 1 between the position below the floating gate 4 and the source 3. This causes an increase in the size of a memory cell, which hinders the reduction of a memory cell area.

In the nonvolatile semiconductor storage device described in Yoshikawa, a control gate extends from the outside of the groove to the inside of the groove. This hinders the formation of a control gate with a stable shape. Further, because the control gate is formed inside the groove, it hinders the reduction of a groove size, which causes an increase in a memory cell area.

### SUMMARY OF THE INVENTION

According to an aspect of the present invention, there is provided a nonvolatile semiconductor storage device which includes a plurality of memory cells, each including a drain formed above a substrate, a source formed at a bottom of a groove in the substrate, a storage node formed above the substrate between the drain and a side surface of the groove, and a control gate formed above the storage node, wherein the groove is shared by adjacent memory cells, the side surface of the groove is substantially aligned with a side end of the storage node, and the groove is filled with an insulating film. This structure allows an offset area to be formed in a depth direction (vertical direction) of the groove of the substrate, thereby enabling the formation of a fine memory cell. Further, because the oxide layer is filled in the groove, the control gate is not formed inside the groove, thereby enabling the formation of a narrow groove.

According to another aspect of the present invention, there is provided a nonvolatile semiconductor storage device which includes a plurality of memory cells, each including a drain formed above a substrate, a source formed at a bottom of a groove in the substrate, a storage node formed above the substrate between the drain and a side surface of the groove, and a control gate formed above the storage node, wherein the groove is shared by adjacent memory cells, the side surface of the groove is substantially aligned with a side end of the storage node, and a distance between the drain and the storage node is shorter than a distance between the source and the control gate in a depth direction of the groove. This structure allows an offset area to be formed in a depth direction (vertical direction) of the groove of the substrate, thereby enabling the formation of a fine memory cell. Further, because the distance between the source and the storage node is shorter than the distance between the source and the control gate in the depth direction of the groove, the control gate is not formed inside the groove, thereby enabling the formation of a narrow groove.

According to yet another aspect of the present invention, there is provided a method of manufacturing a nonvolatile semiconductor storage device in which a groove in a substrate is shared by adjacent memory cells, which includes forming a storage node array with a regular interval by laminating a first insulating film, a polysilicon film, an oxide film, and a nitride film above the substrate and patterning the films, creating a groove in the substrate using the storage node array as a mask, forming a source at a bottom of the groove and a drain above the substrate respectively between lines of the storage node array, and removing the oxide film and the nitride film on the storage node array and laminating a storage node and a control gate. This method allows easy creation of the groove in the substrate using the nitride film on the storage node array as a mask. Further, the offset area can be formed in a depth direction (vertical direction) of the groove of the substrate, thus enabling easy manufacture of a nonvolatile semiconductor storage device which enables formation of a fine memory cell.

The present invention provides a nonvolatile semiconductor storage device and a method of manufacturing the same which enables the reduction of a memory cell area.

### BRIEF DESCRIPTION OF THE DRAWINGS

The above and other objects, advantages and features of the present invention will be more apparent from the following description taken in conjunction with the accompanying drawings, in which:

FIG. 1 is a sectional view showing the structure of a nonvolatile semiconductor storage device according to a first embodiment of the invention;

FIG. 2A is a view to describe a process of manufacturing a nonvolatile semiconductor storage device according to the first embodiment of the invention;

FIG. 2B is a view to describe a process of manufacturing a nonvolatile semiconductor storage device according to the first embodiment of the invention;

FIG. 2C is a view to describe a process of manufacturing a nonvolatile semiconductor storage device according to the first embodiment of the invention;

FIG. 2D is a view to describe a process of manufacturing a nonvolatile semiconductor storage device according to the first embodiment of the invention;

FIG. 2E is a view to describe a process of manufacturing a nonvolatile semiconductor storage device according to the first embodiment of the invention;

FIG. 2F is a view to describe a process of manufacturing a nonvolatile semiconductor storage device according to the first embodiment of the invention;

FIG. 3 is a sectional view showing the structure of a nonvolatile semiconductor storage device according to a second embodiment of the invention; and

FIG. 4 is a sectional view showing the structure of a nonvolatile semiconductor storage device according to a related art.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

### First Embodiment

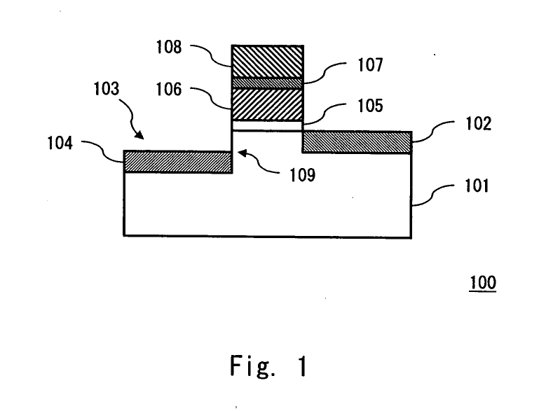

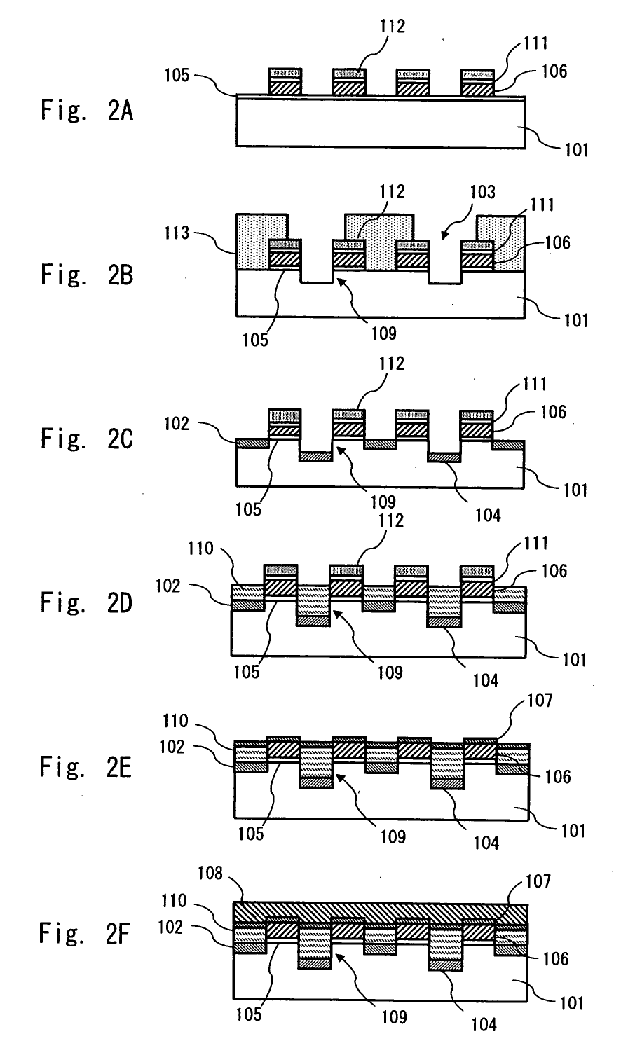

A first exemplary embodiment of the present invention is described hereinafter with reference to FIGS. 1 and 2F. FIG. 1 illustrates the structure of one memory cell in the nonvolatile semiconductor storage device of this embodiment. FIG. 2F illustrates the structure of the nonvolatile semiconductor storage device of this embodiment. As shown in FIG. 1, a memory cell 100 in the nonvolatile semiconductor storage device of this embodiment includes a semiconductor substrate 101, a drain 102, a groove (called a trench) 103, a source 104, a first gate insulating film 105, a floating gate 106, a second gate insulating film 107, a control gate 108, and an offset area 109. This embodiment uses a floating gate as an example of a storage node as described in the claims by way of illustration.

The drain 102 is formed on the surface of the semiconductor substrate 101. The semiconductor substrate 101 has the groove 103, inside which the source 104 is formed on the bottom surface. The first gate insulating film 105 is formed above the semiconductor substrate 101 and between the side end of the drain 102 and the side surface of the groove 103. The floating gate 106 is formed on the first gate insulating film 105. The side end of the floating gate 106 is substantially aligned with the side surface of the groove 103.

The second gate insulating film 107 is formed on the floating gate 106. The control gate 108 is formed on the second gate insulating film 107. The side end of the control gate 108 is substantially aligned with the side surface of the groove 103 and the side end of the floating gate 106. The control gate 108 is not formed inside the groove 103. The control gate 108 therefore has a stable shape. Further, the control gate 108 not being formed inside the groove allows the groove to be narrowed, which enables the reduction of the memory cell area. In this nonvolatile semiconductor storage device, the area between the source 104 and the drain 102 serves as a channel area. The channel area is thus composed of the area below the floating gate 106 and the area along the side surface of the groove 103. The area within the channel area which extends vertically along the side surface of the groove 103 serves as the high-resistance offset area 109. The offset area 109 thus exists along the depth of the groove 103.

In related arts, the offset area is formed horizontally on the surface of the semiconductor substrate between region below the floating gate and the source, which causes an increase in memory cell area. In the present invention, on the other hand, the offset area 109 is formed vertically, which enables the offset area 109 to be determined regardless of the memory cell area (element area). Accordingly, the area of the memory cell does not increase in spite of forming the offset area 109 with a sufficiently large size to thereby realize the formation of a fine memory cell.

As shown in FIG. 2F, though not shown in FIG. 1, an insulating film 110 is disposed on the source 104 and the drain 102 so as to fill the groove 103. On the insulating film 110, the second gate insulating film 107 and the control gate 108 are laminated on one another.

Further, as shown in FIG. 2F, the groove 103 is shared by the adjacent memory cells 100. Stated differently, adjacent transistors share the source 104 which is placed at the bottom of the groove 103 in common. This realizes a high-density memory cell structure, thereby enabling high capacity storage without increasing the size of the semiconductor storage device.

The operation of the nonvolatile semiconductor storage device is described hereinafter. In the write operation, a ground voltage (0V) is applied to the semiconductor substrate 101 and the source 104. Then, the voltage of 14V is applied to the control gate 108 and the voltage of 4.5V is applied to the drain 102, for example. Consequently, high electric field of 1 MV/cm or above is generated in the offset area 109 which is formed along the side surface of the groove 103 in the semiconductor substrate 102. The high electric field accelerates the electrons moving through the channel area to thereby generate hot electrons. The hot electrons then move over the potential barrier of the gate insulating film 105 to be injected into the floating gate 106, thereby writing data to the memory cell.

On the other hand, in the erase operation, the negative voltage of −9V is applied to the control gate 108, and the positive voltage of 9V is applied to the semiconductor substrate 101. The electrons which are accumulated in the floating gate 106 are thereby ejected to the semiconductor substrate 101 through the first gate insulating film 105 due to the FN tunnel current, thereby erasing data from the memory cell. In the read operation, the voltage of 5V is applied to the control gate 108, 2V to the source 104, and 0V to the drain 102, for example. This causes the current to flow through the channel area in the direction reverse to that in the write operation. This current is detected to thereby read data.

Referring now to FIGS. 2A to 2F, a method of manufacturing the nonvolatile semiconductor storage device according to this embodiment is described hereinbelow. FIGS. 2A to 2F are sectional views to describe the manufacturing process of the nonvolatile semiconductor storage device according to this embodiment.

Phosphorus is injected onto the surface of the semiconductor substrate 101 with the conditions of 1.8 MeV, 2*10¹² cm⁻², such that a deep N-well (not shown) is selectively formed. Then, boron is sequentially injected into the deep N-well with the conditions of 30 KeV, 3*10¹³ cm⁻² and 100 KeV, 2*10¹³ cm⁻², such that a P-well is formed. By the ion injection to the semiconductor substrate 101, the high-resistance offset area 109 is formed. It is also possible to form the offset region 109 by the ion injection after forming the groove 103 as described later.

Then, as shown in FIG. 2A, the gate insulating film 105 with the thickness of 8 nm, for example, is deposited on the semiconductor substrate 101. On the first insulating film 105, a first polysilicon layer to serve as the floating gate 106 is deposited. The thickness of the first polysilicon layer may be 80 nm, for example. Then, phosphorus (P) is injected by ion injection to the first polysilicon layer. On the first polysilicon layer, an oxide film 111 with the thickness of 10 nm and a nitride film 112 with the thickness of 120 nm are laminated sequentially. Then, the first polysilicon layer, the oxide film 111, and the nitride film 112 are patterned into a stripe shape to thereby produce a floating gate array. The floating gate array serves as a storage node array as described in the claims.

Next, as shown in FIG. 2B, a resist pattern 113 is formed so as to alternately cover the area between the patterned lines of the floating gate array. Then, using the resist pattern 113 and the nitride film 112 on the floating gate array as a mask, the first gate insulating film 105 and the semiconductor substrate 101 are etched. Due to the presence of the nitride film 112, the accuracy of finishing for the resist pattern 113 is relaxed. Utilizing the nitride film 112, the groove 103 with the depth of about 40 nm is created by self-alignment in the semiconductor substrate 101. Because the groove 103 can be created by self-alignment using the nitride film 112, the groove 103 can be created easily in the semiconductor substrate 101. By this step, the offset area 109 formed in the above step is formed vertically along the side surface of the groove 103. After that, the resist pattern 113 is removed. Then, oxidation treatment is performed on the side surface of the first polysilicon layer to serve as the floating gate 105 and inside the groove 103.

As shown in FIG. 2C, the source 104 is formed inside the groove 103. At the same time, the drain 102 is formed in the part of the surface of the semiconductor substrate 101 between the lines of the floating gate array where the groove 103 is not created. The source 104 and the drain 102 are thereby formed alternately between the lines of the floating gate array. The source 104 and the drain 102 may be formed by the ion injection of arsenic to the semiconductor substrate 101 with the conditions of 2 MeV, 5*10¹⁴ cm⁻², for example. The groove 103 is thereby shared by the adjacent memory cells 100. In other words, adjacent transistors share the source 104 which is placed at the bottom of the groove 103.

Then, the insulating film 110 is deposited on the source 104 and the drain 102. The insulating film 110 is formed so as to fill the area between the lines of the floating gate array. Thus, the groove 103 is filled with the insulating film 110. The insulating film 110 is also deposited on the nitride film 112. The deposited insulating film 110 is then planarized by Chemical Mechanical Polishing (CMP), so that the nitride film 112 is exposed to the surface. The structure shown in FIG. 2D is thereby produced.

Further, the oxide film 111 and the nitride film 112 shown in FIG. 2D are removed by wet etching, so that the top surface of the first polysilicon layer is exposed. The floating gate 106 is thereby formed above the semiconductor substrate 101 with the first gate insulating film 105 interposed therebetween. Because the groove 103 is created using the floating gate array as a mask, the side end of the floating gate 106 which is formed in this step is substantially aligned with the side surface of the groove 103. The second gate insulating film 107 is then deposited on the floating gate 106 and the insulating film 110. The second gate insulating film 107 may be composed of a lamination of an oxide film with the thickness of 5 nm, a nitride film with the thickness of 6 nm, and an oxide film with the thickness of 5 nm. The structure shown in FIG. 2E is thereby produced. Then, as shown in FIG. 2F, a second polysilicon layer to serve as the control gate 108 is deposited. After that, the second polysilicon layer is patterned into the control gate 108. The patterning is performed such that the side end of the control gate 108 and the side surface of the groove 103 are substantially aligned with each other. The control gate 108 is not formed inside the groove 103. This enables the formation of the control gate 108 with a stable shape. In the above process, the nonvolatile semiconductor storage device according to this embodiment is produced.

### Second Embodiment

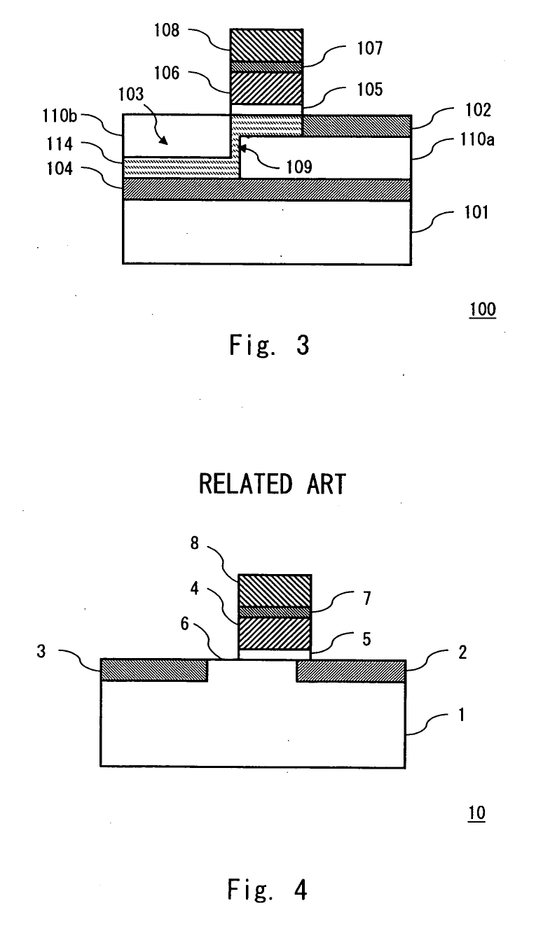

A second exemplary embodiment of the present invention is described hereinafter with reference to FIG. 3. FIG. 3 is a sectional view showing the structure of one memory cell in a nonvolatile semiconductor storage device according to this embodiment. In FIG. 3, the same elements as in FIG. 1 are denoted by the same reference numerals. As shown in FIG. 3, a memory cell 100 in one memory cell in a nonvolatile semiconductor storage device of this embodiment includes a semiconductor substrate 101, a drain 102, a groove 103, a source 104, a first gate insulating film 105, a floating gate 106, a second gate insulating film 107, a control gate 108, an offset area 109, a first insulating film 110a, a second insulating film 110b, and a semiconductor film 114. Although the groove 103 is created directly in the semiconductor substrate 101 in the first embodiment, the groove 103 is created in the first insulating film 110a in this embodiment. Accordingly, the semiconductor substrate 101 with the first insulating film 110a formed thereon serves as a substrate as described in the claims according to this embodiment. This embodiment also uses a floating gate as an example of a storage node as described in the claims by way of illustration.

As shown in FIG. 3, the source 104 is formed on the surface of the semiconductor substrate 101. Further, the first insulating film 110a is formed above a part of the source 104. The groove 103 is created in the first insulating film 110a. Thus, the source 104 is placed at the bottom of the groove 103 which is created in the first insulating film 110a.

The drain 102 is formed on the first insulating film 110a. The semiconductor film 114 is deposited to extend from the side end of the drain 102 to the top end of the groove 103. The semiconductor film 114 is also deposited on the side surface of the groove 103 to extend onto the source 104 where the first insulating film 110a is not formed. Further, the second insulating film 110b is deposited on the semiconductor film 114 which is formed inside the groove 103. The semiconductor film 114 thus extends from the side end of the drain 102 onto the source 104 in the first insulating film 110a and the second insulating film 110b.

The first gate insulating film 105 is deposited on the part of the semiconductor film 114 which lies from the side end of the drain 102 to the top end of the groove 103. The floating gate 106 is formed on the first gate insulating film 105. The floating gate 106 is formed such that its side end is substantially aligned with the side surface of the groove 103.

The second gate insulating film 107 is deposited on the floating gate 106, and the control gate 108 is formed on the second gate insulating film 107. The control gate 108 is formed such that its side end is substantially aligned with the side surface of the groove 103. The control gate 108 is not formed inside the groove 103. This prevents the shape of the control gate 108 from being unstable as described in the first embodiment. This allows the groove to be narrowed, which avoids the problem of an enlarged memory cell area.

In this embodiment, the semiconductor film 114 which is placed between the source 104 and the drain 102 serves as a channel area. Thus, the channel area is the area below the floating gate 106 which lies horizontally with respect to the surface of the semiconductor substrate 101 and the area along the side surface of the groove 103 which lies vertically with respect to the surface of the semiconductor substrate 101. The area of the semiconductor film 114 which exists vertically along the side surface of the groove 103 serves as the high-resistance offset area 109. Thus, the offset area 109 lies along the depth of the groove 103. Because the offset area 109 lies vertically, the offset area 109 can be determined regardless of the memory cell area (element area). Accordingly, the area of the memory cell does not increase in spite of forming the offset area 109 with a sufficiently large size to thereby realize the formation of a fine memory cell.

Although not illustrated therein, the groove 103 is shared by the adjacent memory cells 100. This further reduces the area of one memory cell. This consequently realizes a high-density memory cell structure, thereby enabling high capacity storage without increasing the size of the semiconductor storage device.

In the first and the second embodiments, the nonvolatile semiconductor storage device which has the floating gate 106 as a storage node is described by way of illustration; however, the present invention is not limited thereto. For example, it is possible to use a trap insulating film rather than the floating gate 106 as a storage node. When using a trap insulating film formed of a nitride film, the first gate insulating film 105 may be replaced with a tunnel insulating film formed of an oxide film, and the second gate insulating film 107 may be replaced with a block insulating film formed of an oxide film. In other words, a trap layer with a laminated ONO structure composed of an oxide film, a nitride film and an oxide film is deposited on the channel area between the semiconductor substrate 101 and the control gate 108. In such a case, the charges injected at the time of writing are trapped in the interface between the tunnel insulating film and the trap insulating film.

When manufacturing a nonvolatile semiconductor storage device having such a structure, the groove 103 may be created using as a mask the array of the trap insulating film which is produced by patterning the lamination of an insulating film having three layers with the ONO structure composed of a tunnel insulating film, a trap insulating film and a block insulating film, the control gate 108 formed of the polysilicon film, the oxide film and the nitride film.

Alternatively, it is possible to use silicon dots (semiconductor crystal grains) which are formed as a storage node, separated like an island. For example, the structure may be such that an insulating film containing silicon dots is deposited on the first gate insulating film 105, and the second gate insulating film 107 is deposited thereon. In such a case, the charges injected at the time of writing are trapped in the silicon dots. It is further possible to use metal dots (metal crystal grains) rather than the silicon dots.

As described in the foregoing, the present invention enables reduction of a memory cell area while maintaining a sufficiently large size of the offset area 109. This consequently achieves the provision of a source-injection nonvolatile semiconductor storage device which injects hot electrons through a source to realize a high-density memory cell structure, thereby enabling high capacity storage without increasing the size of the semiconductor storage device.

It is apparent that the present invention is not limited to the above embodiment and it may be modified and changed without departing from the scope and spirit of the invention.

What is claimed is:

1. A nonvolatile semiconductor storage device comprising a plurality of memory cells, each including:
a drain formed above a substrate;
a source formed at a bottom of a groove in the substrate;
a storage node formed above the substrate between the drain and a side surface of the groove; and
a control gate formed above the storage node, wherein
the groove is shared by adjacent memory cells,
the side surface of the groove is substantially aligned with a side end of the storage node, and
the groove is filled with an insulating film.

2. The nonvolatile semiconductor storage device according to claim 1, wherein the storage node is a floating gate.

3. The nonvolatile semiconductor storage device according to claim 1, wherein the storage node is a trap insulating film.

4. The nonvolatile semiconductor storage device according to claim 1, wherein the storage node is a conductive dot.

5. The nonvolatile semiconductor storage device according to claim 1, wherein an area along the side surface of the groove serves as a high-resistance offset area.

6. The nonvolatile semiconductor storage device according to claim 1, wherein a channel area is formed in a close proximity to the side surface of the groove.

7. The nonvolatile semiconductor storage device according to claim 1, further comprising:
a semiconductor film formed on the side surface of the groove and a surface of the substrate in an area between the side end of the drain and the source, wherein a channel area is formed in the semiconductor film.

8. A nonvolatile semiconductor storage device comprising a plurality of memory cells, each including:
a drain formed above a substrate;
a source formed at a bottom of a groove in the substrate;
a storage node formed above the substrate between the drain and a side surface of the groove; and
a control gate formed above the storage node, wherein
the groove is shared by adjacent memory cells,
the side surface of the groove is substantially aligned with a side end of the storage node, and
a distance between the drain and the storage node is shorter than a distance between the source and the control gate in a depth direction of the groove.

9. The nonvolatile semiconductor storage device according to claim 8, wherein the storage node is a floating gate.

10. The nonvolatile semiconductor storage device according to claim 8, wherein the storage node is a trap insulating film.

11. The nonvolatile semiconductor storage device according to claim 8, wherein the storage node is a conductive dot.

12. The nonvolatile semiconductor storage device according to claim 8, wherein an area along the side surface of the groove serves as a high-resistance offset area.

13. The nonvolatile semiconductor storage device according to claim 8, wherein a channel area is formed in a close proximity to the side surface of the groove.

14. The nonvolatile semiconductor storage device according to claim 8, further comprising:
a semiconductor film formed on the side surface of the groove and a surface of the substrate in an area between the side end of the drain and the source, wherein a channel area is formed in the semiconductor film.

15. A method of manufacturing a nonvolatile semiconductor storage device in which a groove in a substrate is shared by adjacent memory cells, the method comprising:
forming a storage node array with a regular interval by laminating a first insulating film, a polysilicon film, an oxide film, and a nitride film above the substrate and patterning the films;
creating a groove in the substrate using the storage node array as a mask;
forming a source at a bottom of the groove and a drain above the substrate respectively between lines of the storage node array; and
removing the oxide film and the nitride film on the storage node array and laminating a storage node and a control gate.

16. The method of manufacturing a nonvolatile semiconductor storage device according to claim 15, further comprising:
depositing a second insulating film above the storage node, wherein
the control gate is formed above the second insulating film.

17. The method of manufacturing a nonvolatile semiconductor storage device according to claim 15, wherein the storage node is formed in the first insulating film.

18. The method of manufacturing a nonvolatile semiconductor storage device according to claim 15, wherein the oxide film is formed to fill between the storage node array above the substrate with the groove.

19. The method of manufacturing a nonvolatile semiconductor storage device according to claim 15, further comprising:
depositing a semiconductor film on the side surface of the groove and a surface of the substrate in an area between a side end of the drain and the source.
